(19) United States
(12) Patent Application Publication
(10) Pub. No.: US 2019/0380200 A1
(43) Pub. Date: Dec. 12, 2019

(54) EMBEDDED COMPONENT STRUCTURE AND MANUFACTURING METHOD THEREOF

(71) Applicant: Unimicron Technology Corp., Taoyuan City (TW)

(72) Inventors: Tzyy-Jang Tseng, Taoyuan City (TW); Yu-Hua Chen, Hsinchu City (TW); Chun-Hsien Chien, New Taipei City (TW); Wen-Liang Yeh, Hsinchu City (TW); Ra-Min Tain, Hsinchu County (TW)

(73) Assignee: Unimicron Technology Corp., Taoyuan City (TW)

(21) Appl. No.: 16/542,291

(22) Filed: Aug. 15, 2019

Related U.S. Application Data
(63) Continuation-in-part of application No. 16/145,130, filed on Sep. 27, 2018.
(60) Provisional application No. 62/645,784, filed on Mar. 20, 2018.

(30) Foreign Application Priority Data
Jul. 27, 2018 (TW) 107126005
Jul. 2, 2019 (TW) 108123227

(51) Int. Cl. H05K 1/02; H05K 1/18; H05K 1/11; H05K 3/30

(52) U.S. Cl. CPC H05K 1/0298; H05K 3/306; H05K 1/111; H05K 1/185

(57) ABSTRACT

An embedded component structure including a circuit board, an electronic component, a dielectric layer and a connection circuit layer and a manufacturing method thereof is provided. The circuit board has a through hole and includes a core layer, a first circuit layer, and a second circuit layer. The first circuit layer and the second circuit layer are disposed on the core layer. The through hole penetrates the first circuit layer and the core layer. The electronic component including a plurality of connection pads is disposed within the through hole where the dielectric layer is filled in. The Young's modulus of the core layer is greater than the Young's modulus of the dielectric layer. The connection circuit layer covers and contacts a first electrical connection surface of the first circuit layer and at least one of a second electrical connection surface of each of the connection pads. A manufacturing method of an embedded component structure is also provided.

### CROSS-REFERENCE TO RELATED APPLICATION

This application is a continuation-in-part application of and claims the priority benefit of U.S. application Ser. No. 16/145,130, filed on Sep. 27, 2018, now pending. The prior U.S. application Ser. No. 16/145,130 claims the priority benefits of U.S. provisional application Ser. No. 62/645,784, filed on Mar. 20, 2018, and Taiwan application serial no. 107126005, filed on Jul. 27, 2018. This application also claims the priority benefit of Taiwan application serial no. 108123227, filed on Jul. 2, 2019. The entirety of each of the above-mentioned patent applications is hereby incorporated by reference herein and made a part of this specification.

### BACKGROUND

### Technical Field

The disclosure relates to an electronic component and a manufacturing method thereof, and more particularly, to an embedded component structure and a manufacturing method thereof.

### Description of Related Art

In a typical embedded component structure, at least one conductive through via is used to electrically connect the electronic component to a printed circuit board (PCB). However, the above connection method makes the electrical transmission path between the electronic component and the printed circuit board long. The power and/or signal of the electronic product might be decreased, and the noise might be increased, thus the S/N ratio might be decreased and the quality of the electronic product might be reduced. Moreover, the manufacturing process of the above embedded component structure is more complicated and has a thicker thickness.

### SUMMARY

The disclosure provides an embedded component structure and a manufacturing method thereof, the thickness may be thinner and the manufacturing method may be relatively simple.

An embedded component structure provided in an embodiment of the invention includes a circuit board, an electronic component, a dielectric material layer, and a connecting circuit layer. The circuit board having a through hole. The circuit board includes a core layer, a first circuit layer, and a second circuit layer. The first circuit layer is disposed on the core layer. The second circuit layer is disposed on the core layer opposite to the first circuit layer. The through hole at least penetrates the first circuit layer and the core layer. The electronic component is disposed in the through hole. The electronic component includes a plurality of connection pads. The connection pads are exposed to the outside of the through hole. The dielectric material layer is at least filled in the through hole. The Young's modulus of the core layer is greater than the Young's modulus of the dielectric layer. The connecting circuit layer is covered and contacted a first electrical connecting surface of the first circuit layer and at least one of a second electrical connecting surface of each of the connection pads. The connecting pads are electrically connected to the first circuit layer by the connecting circuit layer.

In an embodiment of the invention, the dielectric material layer is further filled between each of the connection pads and the first circuit layer and has a dielectric surface coplanar with the first electrical connection surface, and the connecting circuit layer covers and contacts the first electrical connection surface, the dielectric surface, and the second electrical connection surface.

In an embodiment of the invention, on a cross section perpendicular to the first electrical connection surface, a cross-sectional thickness of the connecting circuit layer on the first electrical connecting surface, a cross-sectional thickness of the connecting circuit layer on the dielectric surface, and a cross-sectional thickness of the connecting circuit layer on the second electrical connecting surface are substantially the same.

In an embodiment of the invention, a cross-sectional area of the through hole is larger than a surface area of the second electrical connection surface.

In an embodiment of the invention, the embedded component structure further includes a first dielectric layer. The first dielectric layer is disposed on the same side of the first circuit layer as the core layer and covered at least a portion of the first circuit layer and at least a portion of the connection circuit layer. The first dielectric layer includes at least one opening exposing the first circuit layer or the connection circuit layer.

In an embodiment of the invention, the material of the first dielectric layer includes a solder resist material or a photoimageable dielectric material.

In an embodiment of the invention, the dielectric material layer includes a cover portion outside the through hole, and the cover portion covers a side of the core layer on which the second circuit layer is disposed and covers at least a portion of the second circuit layer.

In an embodiment of the invention, the cover portion of the dielectric material layer includes at least one dielectric opening exposing the second circuit layer.

In an embodiment of the invention, the embedded component structure further includes a second dielectric layer. The second dielectric layer is covered the cover portion of the dielectric material layer. The second dielectric layer includes at least one opening exposing the second circuit layer.

In an embodiment of the invention, the material of the second dielectric layer includes a solder resist material or a photoimageable dielectric material.

In an embodiment of the invention, the through hole is connected to the at least one conductive through hole.

In an embodiment of the invention, the first electrical connection surface of the first circuit layer is coplanar with at least one of the second electrical connection surface of each of the connection pads.

In an embodiment of the invention, the circuit board further includes at least one conductive through hole. The conductive through hole is penetrated the core layer to electrically connect the first circuit layer and the second circuit layer.

A manufacturing method of an embedded component structure provided in an embodiment of the invention includes following steps. A carrier is provided. A circuit board is placed on the carrier. The circuit board includes a through hole. The circuit board includes a core layer, a first circuit layer, and a second circuit layer. The first circuit layer is disposed on the core layer. The second circuit layer is disposed on the core layer opposite to the first circuit layer. The through hole at least penetrates the first circuit layer and the core layer. An electronic component is placed on the carrier. The electronic component includes a plurality of connection pads. The connection pads contact the carrier. After the circuit board and the electronic component are placed on the carrier and the electronic component is embedded in the through hole, a dielectric material layer is formed on the carrier. The dielectric material layer is at least filled in the through hole. The Young's modulus of the core layer is greater than the Young's modulus of the dielectric layer. The carrier is removed to expose the first circuit layer and the connection pads. A first electrical connection surface of the first circuit layer is coplanar with a second electrical connection surface of each of the connection pads. After the carrier is removed, a connection circuit layer is formed. The connection circuit layer covers and contacts the first electrical connection surface and each of the second electrical connection surfaces.

In an embodiment of the invention, the circuit board further includes at least one conductive through hole. The conductive through hole is penetrated the core layer to electrically connect the first circuit layer and the second circuit layer.

In an embodiment of the invention, the through hole is connected to the at least one conductive through hole.

In an embodiment of the invention, the manufacturing method of the embedded component structure further includes the following step. After the connection circuit layer is formed, a first dielectric layer is formed. The first dielectric layer covers at least a portion of the first circuit layer and at least a portion of the connection circuit layer.

In an embodiment of the invention, the material of the first dielectric layer includes a solder resist material.

In an embodiment of the invention, the manufacturing method of the embedded component structure further includes the following steps. After the dielectric material layer is formed, at least one through hole on the circuit board and penetrated the core layer, the first circuit layer, and the second circuit layer is formed. A conductive material is filled into the at least one through hole to form at least one conductive through hole penetrated the core layer. The at least one conductive through hole is electrically connected the first circuit layer and the second circuit layer.

In an embodiment of the invention, the dielectric material layer includes a cover portion outside the through hole, and the cover portion covers a side of the core layer on which the second circuit layer is disposed and covers at least a portion of the second circuit layer.

In an embodiment of the invention, the manufacturing method of the embedded component structure further includes the following step. At least one dielectric opening on the cover portion of the dielectric material layer is formed. The at least one dielectric opening exposes the second circuit layer.

In an embodiment of the invention, the manufacturing method of the embedded component structure further includes the following step. A second dielectric layer is formed to cover the cover portion of the dielectric material layer.

In an embodiment of the invention, the manufacturing method of the embedded component structure further includes the following step. At least one second opening is formed on the second dielectric layer. The at least one second opening exposes the second circuit layer.

In an embodiment of the invention, the material of the second dielectric layer includes a solder resist material or a photoimageable dielectric material.

Based on the above, in the embedded component structure of the present invention, the electronic component and the circuit board are electrically connected via the connection circuit layer therebetween, and the via hole between the electronic component and the circuit board could no need to be formed or omitted. Therefore, the manufacturing process of the embedded component structure could be simpler and has a thinner thickness. In addition, the circuit path between the electronic component and the circuit board may be reduced via the connection circuit layer, and the signal transmission time (i.e., delay time) may be reduced, and the transmission rate between different electronic components may be improved.

To make the above features and advantages provided in one or more of the embodiments of the disclosure more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles described herein.

FIG. 1A to FIG. 1H are schematic cross-sectional views of a manufacturing method of an embedded component structure according to a first embodiment of the invention.

FIG. 1I is a schematic top view of an embedded component according to a first embodiment of the invention.

FIG. 2 is a schematic cross-sectional view of an embedded component according to a second embodiment of the invention.

FIG. 3A to FIG. 3E are schematic cross-sectional views of a manufacturing method of an embedded component structure according to a third embodiment of the invention.

FIG. 4A, FIG. 4B and FIG. 4D are schematic bottom views of a manufacturing method of an embedded component structure according to a fourth embodiment of the invention.

FIG. 4C, FIG. 4E to FIG. 4H are schematic cross-sectional views of a manufacturing method of an embedded component structure according to a fourth embodiment of the invention.

FIG. 5A to FIG. 5F are schematic cross-sectional views of a manufacturing method of an embedded component structure according to a fifth embodiment of the invention.

FIG. 5G is a schematic top view of an embedded component according to a fifth embodiment of the invention.

FIG. 6 is a schematic cross-sectional view of an embedded component according to a sixth embodiment of the invention.

FIG. 7 is a schematic cross-sectional view of an embedded component according to a seventh embodiment of the invention.

FIG. 8 is a schematic cross-sectional view of an embedded component according to an eighth embodiment of the invention.

FIG. 9 is a schematic cross-sectional view of an embedded component according to a ninth embodiment of the invention.

### DESCRIPTION OF THE EMBODIMENTS

In the following detailed description of the embodiments, reference is made to the accompanying drawings which form a part hereof, and in which are shown by way of illustrating specific embodiments in which the invention may be practiced. In this regard, directional terminology, such as “top,” “bottom,” “front,” “back,” “left,” “right,” etc., is used with reference to the orientation of the Figure(s) being described. The components provided in one or some embodiments of the invention may be positioned in a number of different orientations.

In the detailed description of the embodiments, the terms “first”, “second”, “third”, “fourth” and the like may be used to describe different elements. These terms are only used to distinguish elements from each other, but in the structure, these elements may not be limited by these terms. For example, a first element may be referred to as a second element, and similarly, a second element may be referred to as a first element without departing from the scope of the inventive concept. In addition, in the manufacturing method, the formation of these elements or components may not be limited by these terms except for a specific process flow. For example, the first element may be formed before the second element. Or, the first element may be formed after the second element. Alternatively, the first element and the second element may be formed in the same process or step.

The thickness of layer(s) or region(s) in the drawings may be exaggerated for clarity. Identical or similar devices are given identical or similar reference numerals in any of the following embodiments.

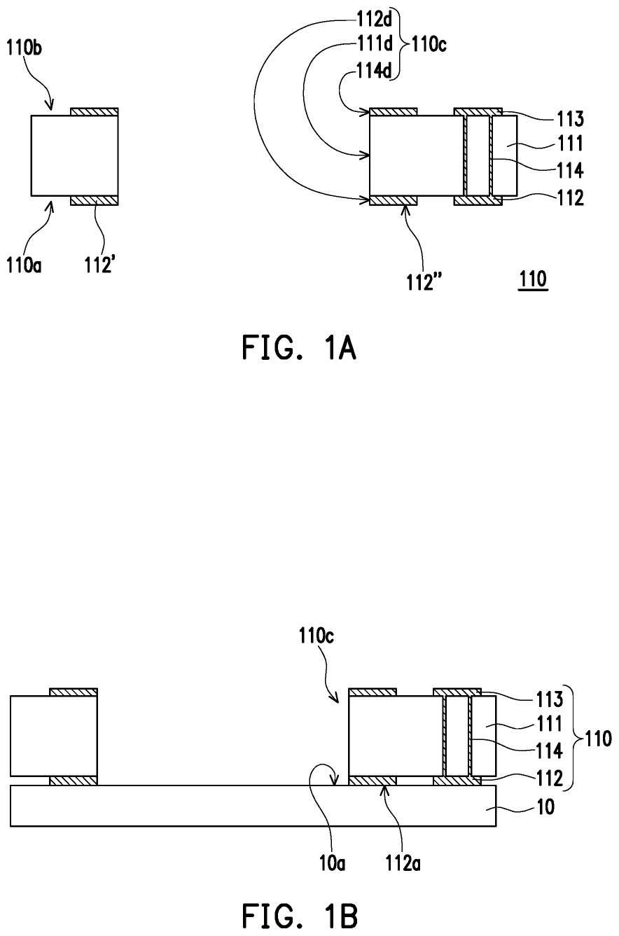

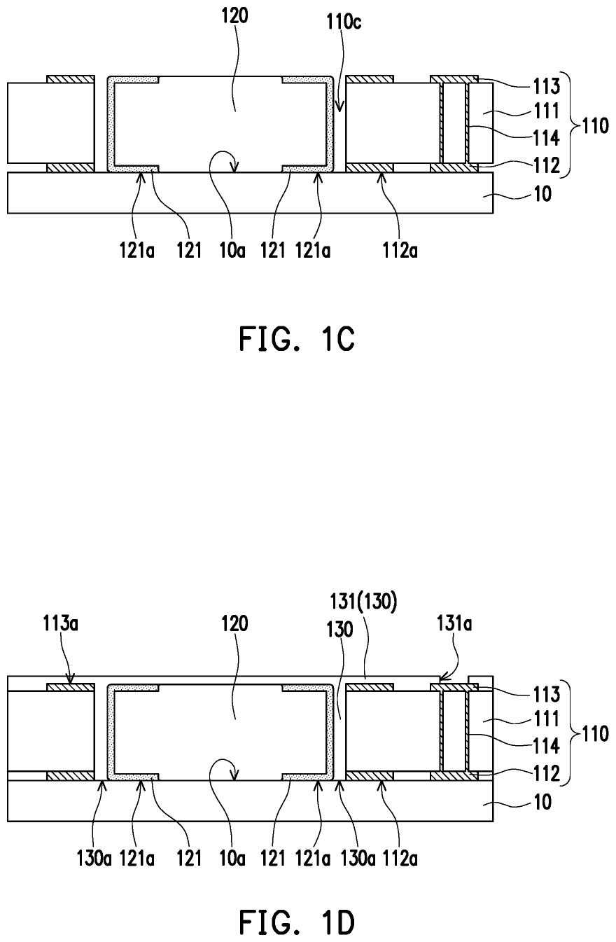

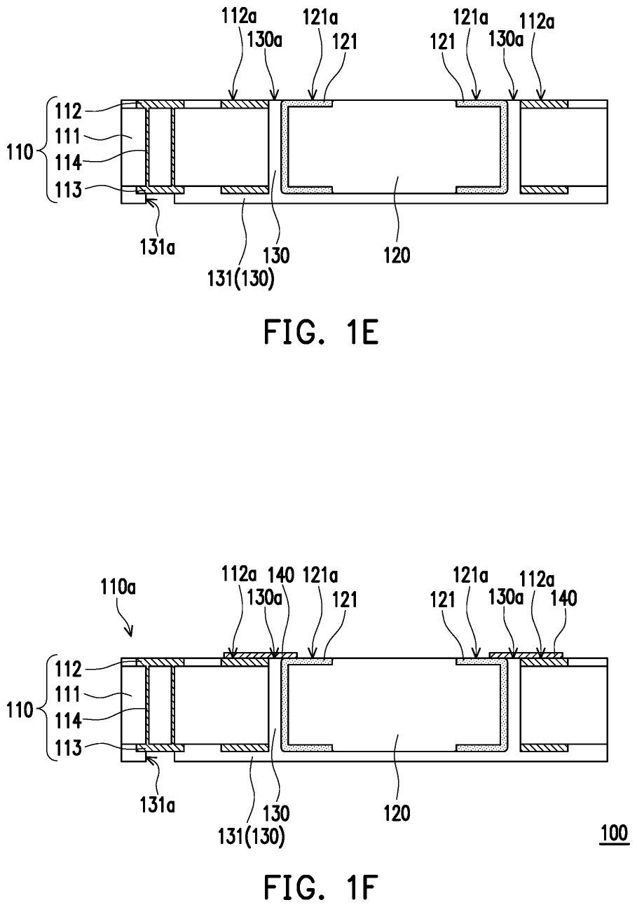

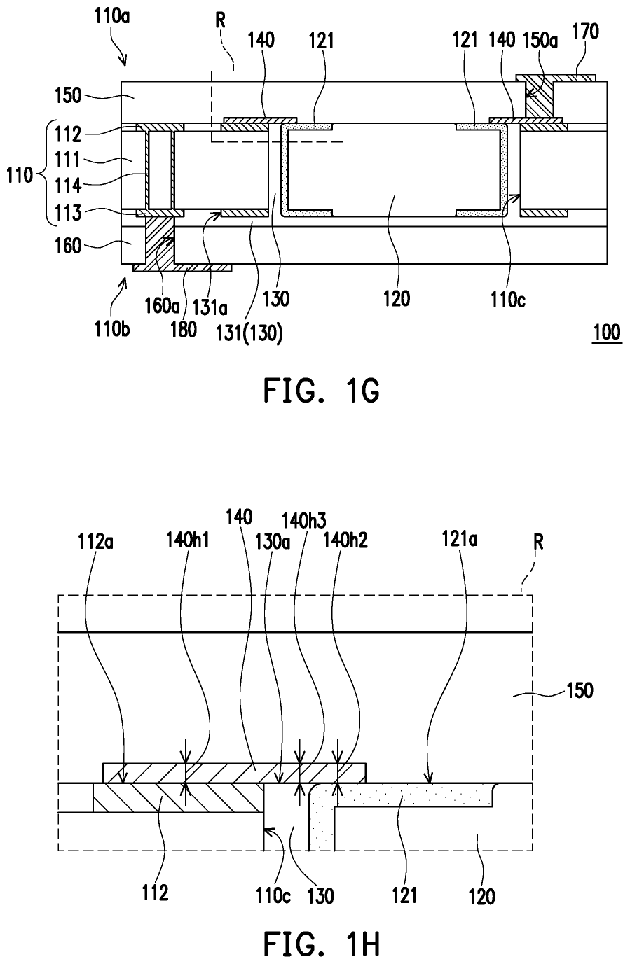

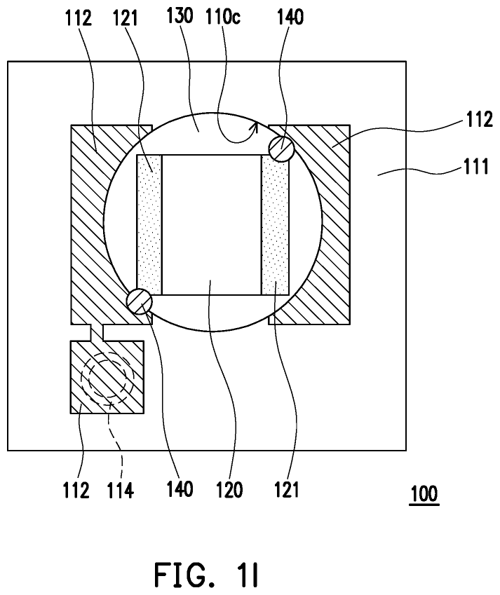

FIG. 1A to FIG. 1H are schematic cross-sectional views of a manufacturing method of an embedded component structure according to a first embodiment of the invention. FIG. 1I is a schematic top view of an embedded component according to a first embodiment of the invention. In particular, FIG. 1H may be an enlarged view of region R3 in FIG. 1G.

Referring to FIG. 1A, a circuit board 110 is provided. The circuit board 110 includes a core layer 111, a first circuit layer 112, and a second circuit layer 113. The first circuit layer 112 is disposed on the core layer 111 and on the first side 110a of the circuit board 110. The second circuit layer 112 is disposed on the core layer 111 and on the second side 110b of the circuit board 110. The first side 110a is opposite the second side 110b. The circuit board 110 has a through hole 110c. The through hole 110c penetrates at least the first circuit layer 112 and the core layer 111. In other words, the through hole 110c is composed of at least a side wall 111d of the core layer 111 and a side wall 112d of the first circuit layer 112. The first circuit layer 112′ and the first circuit layer 112″ are disposed on two sides of the through hole 110c, and the first circuit layer 112′ and the first circuit layer 112″ are structurally and electrically separated from each other.

In the embodiment, the through hole 110c further penetrates the second circuit layer 113. In other words, in the embodiment, the through slot 110c may be composed of the side wall 111d of the core layer 111, the side wall 112d of the first line layer 112, and the side wall 113d of the second line layer 113.

In the embodiment, the core layer 111 may include a polymer glass fiber composite substrate, a glass substrate, a ceramic substrate, a silicon-on-insulator substrate, a polyimide (PI) glass fiber composite substrate, or a substrate made of a material having a higher Young's modulus (compared to the subsequent dielectric material layer 130). As such, in a subsequent process, the circuit board 110 may be adapted to carry the film layer formed thereon or a component, an element, or a device disposed thereon.

In the embodiment, the core layer 111 of the circuit board 110 is made of a material having a higher Young's modulus. Thus, during the fabrication of the embedded component structure 100 (labeled in FIG. 1F, 1G, or 1I), the core layer 111 may be used as a support for the manufacturing process or the overall final structure.

In an embodiment, the Young's modulus of the core layer 111 may be greater than or equal to 70 Gigapascal (GPa).

In the embodiment, the core layer 111 may be formed a double sided circuit board with the first circuit layer 112 and the second circuit layer 113 on opposite sides of the core layer 111. For example, the circuit board 110 may be a copper clad laminate (CCL) or other suitable printed circuit board, but the invention is not limited thereto.

In an embodiment, the circuit board 110 may be referred to as a hard board PCB.

In some embodiments, the first circuit layer 112 and/or the second circuit layer 113 may be one or more conductive layers, but the invention is not limited thereto. Moreover, if the first circuit layer 112 and/or the second circuit layer 113 are formed by a plurality of conductive layers, the multi-layered conductive layers may be separated from each other by one or more insulating layers, and different conductive layers may be electrically connected to each other by one or more conductive via. The conductive via is, for example, a buried via hole (BVH), but the invention is not limited thereto.

In the embodiment, the circuit board 110 may further include at least one conductive through hole 114. The first circuit layer 112 on the first side 110a and the second circuit layer 113 on the second side 110b may be electrically connected to each other via the conductive through hole 114. In other embodiments, a similar circuit board may have no conductive through hole.

In the embodiment, the conductive through hole 114 may be a hollow plating through hole (PTH), but the invention is not limited thereto. In some embodiments, the conductive through hole 114 may be a solid conductive pillar. In some embodiments, the core of the conductive through hole 114 may be stuffed with a hole plugging resin material or a polymer glass-ceramic mixed material, but the invention is not limited thereto.

Referring to FIG. 1B, a carrier 10 is provided. Moreover, the carrier 10 is bonded to the circuit board 110 in such a manner that the first electrical connection surface 112a (i.e., the exposed surface of the first circuit layer 112 that is furthest from the core layer 111) of the first circuit layer 112 on the core layer 111 faces the carrier surface 10a of the carrier 10. The carrier 10 may be a carrier tape, such as a blue tape, but the invention is not limited thereto. In other embodiments, the carrier 10 may be a metal substrate, a silicon substrate, a glass substrate, a ceramic substrate, or other suitable carrier that may be used for support a certain component, element, or device (e.g., the electronic component 120 that will be disposed on the carrier 10 in a subsequent process). In other words, in some embodiments, the carrier 10 may be not suitable for supporting the entire structure.

As shown in FIG. 1B, after the carrier 10 is bonded to the circuit board 110, the first circuit layer 112 contacts the carrier 10. In the embodiment, the first electrical connection surface 112a of the first circuit layer 112 may directly contact the carrier surface 10a of the carrier 10, but the invention is not limited thereto. In other embodiments, if an adhesive layer (such as a release film) is disposed between the circuit board 110 and the carrier 10, the first electrical connection surface 112a of the first circuit layer 112 may indirectly contact the carrier 10. In general, the thickness of the carrier 10 or the thickness of the circuit board 110 may be a millimeter (mm) scale or a centimeter (cm) scale, and the thickness of the adhesive layer may be of a micrometer (μm) scale. In other words, the thickness of the adhesive layer may be very thin compared to the thickness of the carrier 10 or the thickness of the circuit board 110. Therefore, in the general visual sense, even if an adhesive layer is disposed between the circuit board 110 and the carrier 10, the first circuit layer 112 may be regarded as contacting the carrier 10.

In the embodiment, the size of the carrier 10 is only required to be larger than the size of the through hole 110c. That is, the surface area of the carrier surface 10a of the carrier 10 is only required to be larger than the opening area of the through hole 110c. For example, the size of the carrier 10 may be less than or equal to the size of the circuit board 110 and larger than the size of the through hole 110c. As such, after the carrier 10 is bonded to the circuit board 110, the carrier surface 10a of the carrier 10 may completely cover the opening of the through hole 110c.

Referring to FIG. 1C, an electronic component 120 is placed on the carrier 10. Specifically, the electronic component 120 may have a plurality of connection pads 121 on one side thereof, and the electronic component 120 is disposed on the carrier 10 in such a manner that the second electrical connection surface 121a of each of the connection pads 121 of the electronic component 120 faces the carrier surface 10a of the carrier 10.

As shown in FIG. 1C, after the electronic component 120 is disposed on the carrier 10, the connection pads 121 contact the carrier 10. In the embodiment, the second electrical connection surface 121a of each of the connection pads 121 may directly contact the carrier surface 10a of the carrier 10, but the invention is not limited thereto. In other embodiments, if an adhesive layer (i.e., a release film) is disposed between the electronic component 120 and the carrier 10, the second electrical connection surface 121a of each of the connection pads 121 may indirectly contact the carrier 10. The electronic component 120, for example, a multilayer ceramic capacitor (MLCC). A thickness of a 0402 series MLCC (0402 MLCC) is about 500 μm, and a thickness of a 0603 series MLCC (0603 MLCC) is about 800 μm. In other words, the thickness of the adhesive layer may be very thin compared to the thickness of the electronic component 120. Therefore, in the general visual sense, even if an adhesive layer is disposed between the electronic component 120 and the carrier 10, the electronic component 120 may be regarded as contacting the carrier 10.

In the embodiment, the carrier 10 may be bonded to the circuit board 110, then, the electronic component 120 is disposed on the carrier 10, and the electronic component 120 is embedded in the through hole 110c of the circuit board 110, but the invention is not limited thereto. In other embodiments, the electronic component 120 may be disposed on the carrier 10, then, the carrier 10 with the electronic component 120 disposed thereon may be bonded to the circuit board 110, and the through hole 110c of the circuit board 110 may be aligned with the electronic component 120 to embed the electronic component 120 into the through hole 110c of the circuit board 110.

In the embodiment, the thickness of the circuit board 110 may be the same as or different from the thickness of the electronic component 120, but the invention is not limited thereto. It should be noted that the cross-sectional area of the through hole 110c of the circuit board 110 should be larger than the cross-sectional area of the electronic component 120 on the side of the connection pads 121, so that the electronic component 120 is suitably embedded in the through hole 110c of the circuit board 110, and the connection pads 121 of the electronic component 120 could be exposed to the outside of the through hole 110c.

Referring to FIG. 1D, after the circuit board 110 and the electronic component 120 are placed on the carrier 10, and the electronic component 120 is embedded in the through hole 110c, a dielectric material layer 130 is formed on the carrier 10, and the dielectric material layer 130 is at least filled in the through hole 110c (shown in FIG. 1C). In the embodiment, for example, a resin (i.e., epoxy or other similar thermosetting cross-linked resin), silane (i.e., hexamethyldisiloxane (HMDSN), tetraethoxysilane (TEOS), bis(dimethylamine)dimethylsilane (BDMADMS)) or other suitable dielectric material is coated on the carrier 10 and cured, and to be formed the dielectric material layer 130. In general, the aforementioned dielectric materials may have better adhesion and may not require a higher (compared to the core layer 111) Young's modulus. For example, the Young's modulus of the epoxy resin can be less than 5 GPa, and the Young's modulus of the silicone can be less than 1 GPa. That is to say, in the structure illustrated in FIG. 1D, the entire structure may be supported by the core layer 111 basically.

In the embodiment, the dielectric material layer 130 may be filled in the through hole 110c and disposed between the electronic component 120 and the circuit board 110. As such, the electronic component 120 may be fixed in the through hole 110c of the circuit board 110. In addition, since the dielectric material layer 130 may be formed of a material having a lower Young's modulus (compared to the core layer 111), the dielectric material layer 130 may be provided as a buffer between the electronic component 120 and the circuit board 110.

In an embodiment, the Young's modulus of the dielectric material layer 130 may be less than or equal to 10 Gigapascal (GPa).

In the embodiment, the dielectric material layer 130 filled in the through hole 110c may contact the carrier 10, but the invention is not limited thereto.

In the embodiment, the dielectric material layer 130 may include a cover portion 131. The cover portion 131 is disposed outside the through hole 110c and covers the second circuit layer 113.

In the embodiment, at least one dielectric opening 131a may be formed in the cover portion 131 by etching, grinding drilling, laser drilling, or other suitable process.

In the embodiment, the dielectric opening 131a may expose the conductive through hole 114, but the invention is not limited thereto. In other embodiments, the dielectric opening 131a may expose the third electrical connection surface 113a of the second circuit layer 113 (i.e., the exposed surface of the second circuit layer 113 that is farthest from the core layer 111).

Referring to FIG. 1E, after forming the dielectric material layer 130, the carrier 10 (shown in FIG. 1D) and the adhesive layer (if any) on the carrier 10 are removed to expose the first electrical connection surface 112a of the first circuit layer 112 and the second electrical connection 121a of each connection pads 121. Since the circuit board 110 and the electronic component 120 are both disposed on the carrier 10 and in contact (direct contact if there is no adhesive layer, or indirectly contact if there is an adhesive layer) with the carrier 10, the first electrical connection surface 112a of the first circuit layer 112 and the second electrical connection surface 121a of each connection pad 121 may be substantially coplanar.

In the embodiment, if the dielectric material layer 130 filled in the through hole 110c (shown in FIG. 1C) contacts (including directly contact or indirectly contact as mentioned above) the carrier 10, the dielectric surface 130a of the dielectric material layer 130, the first electrical connection surface 112a of the first circuit layer 112, and the second electrical connection surface 121a of each connection pads 121 may be substantially coplanar.

In addition, the structure of FIG. 1D may be flipped upside down before or after the carrier 10 is removed. So that after the carrier 10 is removed, a structure as shown in FIG. 1E may be constructed. That is to say, in the structure illustrated in FIG. 1E, the entire structure may be supported by the core layer 111 basically.

Referring to FIG. 1F, a connection circuit layer 140 is formed. The connection circuit layer 140 is a film layer covering and contacting the first electrical connection surface 112a and at least one of the second electrical connection surfaces 121a. The connection circuit layer 140 may be formed by a redistribution layer process (RDL process) or other suitable patterned circuit process.

One of the exemplary processes for forming the connection circuit layer 140 may be briefly described below. First, a seed layer (not shown) may be formed on the first side 110a of the circuit board 110 by sputtering. The seed layer is conformal with the first electrical connection surface 112a of the first circuit layer 112, the second electrical connection surface 121a of the connection pad 121, and the dielectric surface 130a of the dielectric material layer 130. A general seed layer includes a titanium layer and/or a copper layer. However, the actual material of the seed layer depends on the conductive material that will be subsequently formed on the seed layer. Next, a photoresist layer (not shown) is formed on the seed layer. The photoresist layer covers a portion of the seed layer. The photoresist layer may be formed by a coating process, a lithography process and an etching process. The photoresist layer has a plurality of openings corresponding to the first electrical connection surface 112a, the second electrical connection surface 121a, and the dielectric surface 130a. The openings expose a portion of the seed layer above the first electrical connection surface 112a, the second electrical connection surface 121a, and the dielectric surface 130a. After the photoresist layer is formed, a conductive material layer (not shown) may be formed on the seed layer exposed by the openings. The conductive material layer may be formed on the seed layer by electroplating. The material of the conductive material layer may be similar to the material of the seed layer, but the invention is not limited thereto. After forming the conductive material layer, the photoresist layer and a portion of the conductive material layer on the photoresist layer are removed. Next, another portion of the conductive material layer that has not been removed is used as a mask to remove a portion of the seed layer that is not covered by the another portion of the conductive material layer. As such, the seed layer that has not been removed and the layer of conductive material that has not been removed may constitute the connection circuit layer 140.

Referring to FIG. 1G, after the connection circuit layer 140 is formed, a first dielectric layer 150 is formed on the first side 110a of the circuit board 110. The first dielectric layer 150 may be formed by a deposition process or a coating process. Then, a photolithography process and an etching process may be performed for patterning, and to form a first dielectric opening 150a exposing portion of the first circuit layer 112 and/or a portion of the connection circuit layer 140.

In the embodiment, a second dielectric layer 160 may be formed on the second side 110b of the circuit board 110. The second dielectric layer 160 may be formed by a deposition process or a coating process. Then, a photolithography process and an etching process may be performed for patterning, and to form a second dielectric opening 160a exposing portion of the second circuit layer 113.

In the embodiment, after the first dielectric layer 150 is formed, a third circuit layer 170 may be formed on the first dielectric layer 150. The way to form the third circuit layer 170 may be similar to the aforementioned way to form the connection circuit layer 140, and thus is not described in detail herein. In addition, the first dielectric opening 150a of the first dielectric layer 150 may be further filled with the conductive material used to form the third circuit layer 170, so as the third circuit layer 170 may be electrically connected to the first circuit layer 112 and/or the connection circuit layer 140.

In the embodiment, after the second dielectric layer 160 is formed, a fourth circuit layer 180 may be formed on the second dielectric layer 160. The way to form the fourth circuit layer 180 may be similar to the aforementioned way to form the connection circuit layer 140, and thus is not described in detail herein. In addition, the second dielectric opening 160a of the second dielectric layer 160 may be further filled with the conductive material used to form the fourth circuit layer 180, so as the fourth circuit layer 180 may be electrically connected to the second circuit layer 113 and/or the conductive through hole 114.

Referring to FIG. 1G to FIG. 1I, after the above manufacturing process is performed, an embedded component structure 100 provided in the present embodiment is substantially formed. The embedded component structure 100 described above includes a circuit board 110, an electronic component 120, a dielectric material layer 130, and a connection circuit layer 140. The circuit board 110 has a through hole 110c. The circuit board 110 includes a core layer 111, a first circuit layer 112, a second circuit layer 113, and at least one conductive through hole 114. The first circuit layer 112 and the second circuit layer 113 are disposed on opposite sides of the core layer 111 respectively. The through hole 110c penetrates the first circuit layer 112, the core layer 111, and the second circuit layer 113. The conductive through hole 114 penetrates through the core layer 111 to electrically connect the first circuit layer 112 and the second circuit layer 113. The electronic component 120 is disposed in the through hole 110c. The electronic component 120 includes a plurality of connection pads 121. In the upper view, a plurality of connection pads 121 are exposed outside the through hole 110c. In the cross-sectional view, the first electrical connection surface 112a of the first circuit layer 112 is substantially coplanar with the second electrical connection surface 121a of each of the connection pads 121. The dielectric material layer 130 is at least filled in the through hole 110c. The Young's modulus of the core layer 111 is greater than the Young's modulus of the dielectric material layer 130. The connection circuit layer 140 covers and contacts the first electrical connection surface 112a and each of the second electrical connection surfaces 121a. The connection pad 121 is electrically connected to the first circuit layer 112 by the connection circuit layer 140.

In the embodiment, the dielectric material layer 130 is further filled between each of the connection pads 121 and the first circuit layer 112. The dielectric material layer 130 has a dielectric surface 130a. The dielectric surface 130a is substantially coplanar with the first electrical connection surface 112a. The connection circuit layer 140 covers and contacts the first electrical connection surface 112a, the dielectric surface 130a, and the second electrical connection surface 121a.

In the embodiment, in the cross-sectional view, on a cross section perpendicular to the first electrical connection surface 112a, the cross-sectional thickness 140h of the connecting circuit layer 140 on the first electrical connecting surface 112a, the cross-sectional thickness 140h3 of the connecting circuit layer 140 on the dielectric surface 130a, and the cross-sectional thickness 140h2 of the connecting circuit layer 140 on the second electrical connecting surface 121a are substantially the same.

In the embodiment, in the upper view, the cross-sectional area of the through hole 110c is larger than the surface area of the second electrical connection surface 121a.

In the embodiment, the embedded component structure 100 further includes a first dielectric layer 150. The first dielectric layer 150 and the first circuit layer 112 are disposed on the same side of the core layer 111. The first dielectric layer 150 covers at least a portion of the first circuit layer 112 and at least a portion of the connection circuit layer 140. The first dielectric layer 150 has at least one first dielectric opening 150a exposing the first circuit layer 112 or the connection circuit layer 140.

In the embodiment, the dielectric material layer 130 has a cover portion 131 located outside the through hole 110c. The cover portion 131 covers the side of the core layer 111 on which the second circuit layer 113 is disposed. The cover portion 131 covers at least a portion of the second circuit layer 113.

In the embodiment, the cover portion 131 of the dielectric material layer 130 has at least one dielectric opening 160a exposing the second circuit layer 113 or the conductive through hole 114.

In the embodiment, the embedded component structure 100 further includes a second dielectric layer 160. The second dielectric layer 160 and the second circuit layer 113 are disposed on the same side of the core layer 111. The second dielectric layer 160 covers at least a portion of the second circuit layer 113 and at least a portion of the conductive through hole 114. The second dielectric layer 160 has at least one second dielectric opening 160a exposing the second circuit layer 113 or the conductive through hole 114.

Based on the above, the electronic component 120 and the circuit board 110 are electrically connected via the connection circuit layer 140 therebetween, and the via hole between the electronic component 120 and the circuit board 110 could no need to be formed or omitted (not shown because none). Therefore, the manufacturing process of the embedded component structure 100 could be simpler and has a thinner thickness. In addition, the circuit path between the electronic component 120 and the circuit board 110 may be reduced via the connection circuit layer 140, and the signal transmission time may be reduced, and the transmission rate between different electronic components may be improved. Moreover, the circuit board 110 is not completely removed during the manufacturing process of the embedded component structure 100. Therefore, in the manufacturing method of the embedded component structure 100, the circuit board 110 needs to have better supportability (e.g., by having the core layer 111 having a higher Young's modulus).

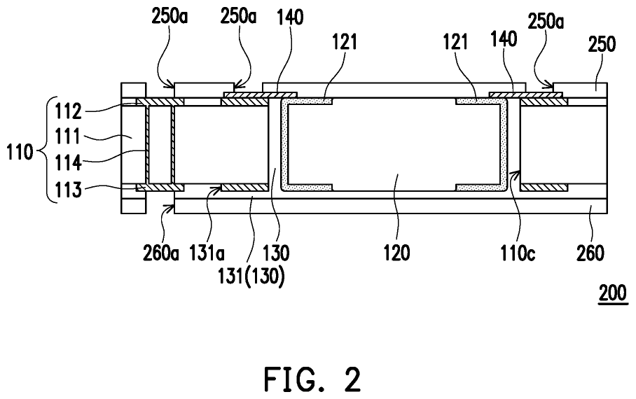

FIG. 2 is a schematic cross-sectional view of an embedded component according to a second embodiment of the invention.

The manufacturing processes of the embedded component structure 200 provided in the present embodiment are similar to the manufacturing processes of the embedded component structure 100 provided in the first embodiment, and similar components are marked by identical or similar reference numerals and have similar function, material, or may be formed in a similar manner, and thus relevant descriptions are omitted hereinafter. Structurally, the embedded component structure 200 of the present embodiment is similar to the embedded component structure 100 of the first embodiment, with the main difference being that the material of the first dielectric layer 250 includes a solder resist material and/or the material of the second dielectric layer 260 includes a solder resist material.

In the embodiment, the first dielectric layer 250 may be a photoimageable dryfilm solder mask (DFSM) or a liquid photoimageable solder mask (LPSM). The first dielectric layer 250 may have a plurality of first dielectric openings 250a. The first dielectric opening 250a may expose a corresponding portion of the first circuit layer 112, a portion of the connection circuit layer 140, and/or a portion of the conductive through hole 114.

In the embodiment, the second dielectric layer 260 may be a dry film solder mask or a liquid photosensitive solder resist. The second dielectric layer 260 has at least one second dielectric opening 260a. The second dielectric opening 260a may expose a corresponding portion of the conductive through hole 114. In other embodiments, the second dielectric opening 260a may expose a corresponding portion of the second circuit layer 113.

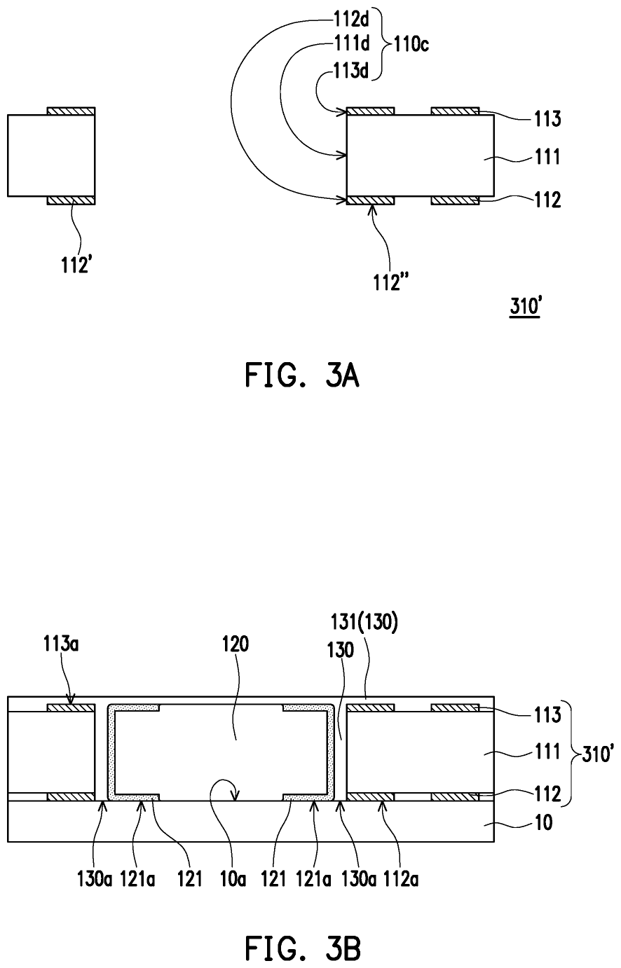

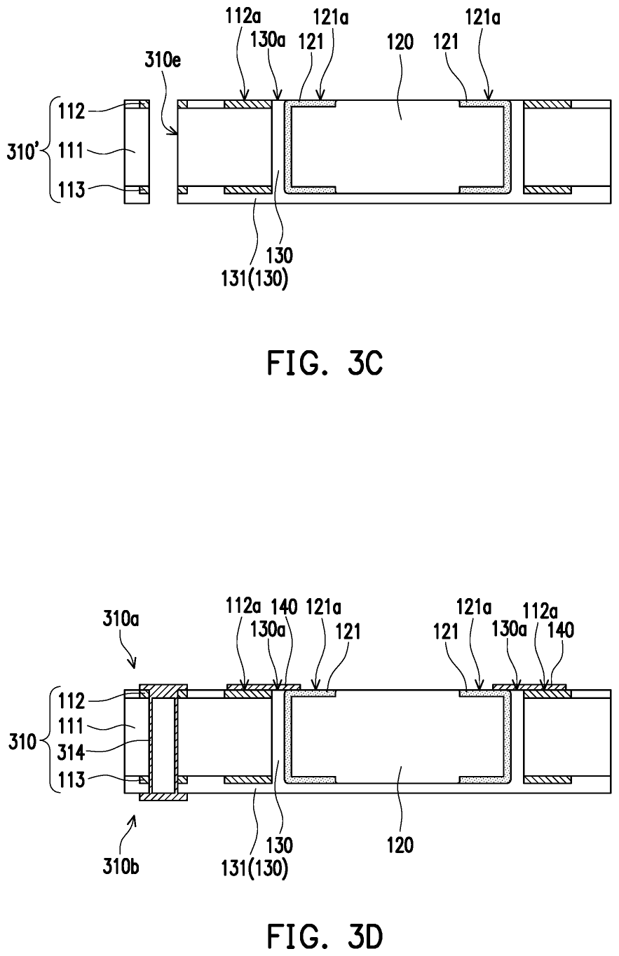

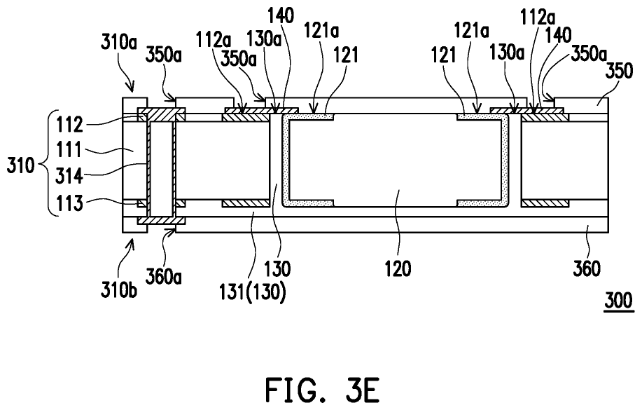

FIG. 3A to FIG. 3E are schematic cross-sectional views of a manufacturing method of an embedded component structure according to a third embodiment of the invention.

The manufacturing processes of the embedded component structure 300 provided in the present embodiment are similar to the manufacturing processes of the embedded component structure 100 provided in the first embodiment, and similar components are marked by identical or similar reference numerals and have similar function, material, or may be formed in a similar manner, and thus relevant descriptions are omitted hereinafter.

Referring to FIG. 3A, a circuit board 310′ is provided. Structurally, the circuit board 310′ in FIG. 3A is similar to the circuit board 110 in FIG. 1A, with the main difference being that the circuit board 310′ has no conductive through hole (not shown because none).

Then, the circuit board 310′ and the electronic component 120 may be disposed on the carrier 10 by steps similar to those of FIGS. 1A to 1D, and the electronic component 120 may be embedded in the through hole 110c. Then, a dielectric material layer 130 is formed on the carrier 10, and the dielectric material layer 130 is filled at least in the through hole 110c (shown in FIG. 3A) to form a structure as shown in FIG. 3B.

Referring to FIG. 3C, the structure of FIG. 3B may be flipped upside down before or after the carrier 10 is removed, so that after the carrier 10 is removed, at least one through hole 310e on the circuit board 310′ may be formed by etching, grinding drilling, laser drilling, or other suitable process. The through hole 310e penetrates the core layer 111, the first circuit layer 112, and the second circuit layer 113.

It is to be noted that the order of removing the carrier 10, flipping up-and-down, and forming at least one through hole 310e aforementioned are not limited in the present embodiment. In other words, the aforementioned three steps may be adaptively adjusted in the order according to the requirements of the manufacturing process.

In the embodiment, since the electronic component 120 has been embedded in the through hole 110c (shown in FIG. 3A) of the circuit board 310′, and the dielectric material layer 130 filled in the through hole 110c may fix the electronic component 120 in the through hole 110c and provide a buffer between the electronic component 120 and the circuit board 310′. Therefore, in the process of forming the through hole 310e, although the electronic component 120 or the circuit board 310′ may be affected by stress (for example, vibration during hole drilling to cause stress between the electronic component 120 or the circuit board 310′), the offset of the electronic component 120 may be reduced.

Referring to FIG. 3D, after the carrier 10 (shown in FIG. 3B) is removed and at least one through hole 310e (shown in FIG. 3C) is formed, the connection circuit layer 140 is formed. Further, a conductive material is filled in the through hole 310e to form the conductive through hole 314 by a method similar to the method of forming the connection circuit layer 140. For example, the conductive through hole 314 and the connection circuit layer 140 may be formed during the same process. A seed layer for forming the connection circuit layer 140 or a conductive material covering the seed layer may be filled in the through hole 310e to form the conductive through hole 314. The conductive through hole 314 may be electrically connected to the first circuit layer 112 and the second circuit layer 113. The circuit board 310 having the core layer 111, the first circuit layer 112, the second circuit layer 113, and the conductive through hole 314 may be formed.

Referring to FIG. 3E, after the connection circuit layer 140 and the conductive through hole 314 are formed, the first dielectric layer 350 may be formed on the first side 310a of the circuit board 310. The first dielectric layer 350 has at least one first dielectric opening 350a. The first dielectric opening 350a exposes a portion of the first circuit layer 112, a portion of the connection circuit layer 140, and/or a portion of the conductive through hole 314.

In the embodiment, a second dielectric layer 360 may be formed on the second side 310b of the circuit board 310. The second dielectric layer 360 has at least one second dielectric opening 360a. The second dielectric opening 360a exposes a portion of the second circuit layer 113 and/or a portion of the conductive through hole 314.

In other embodiments, the first dielectric layer 350 and/or the second dielectric layer 360 may be a dry film solder resist or a liquid photosensitive solder resist.

After the above manufacturing process is performed, an embedded component structure 300 provided in the present embodiment is substantially formed. The embedded component structure 300 of the present embodiment is similar to the embedded component structure 100 of the first embodiment, with the main difference being that the embedded component structure 300 of the present embodiment is formed by first embedding the electronic component 120 in the through trench 110c of the circuit board 310′ having no conductive through hole, and then the circuit board 310 having the conductive through hole 314 is formed.

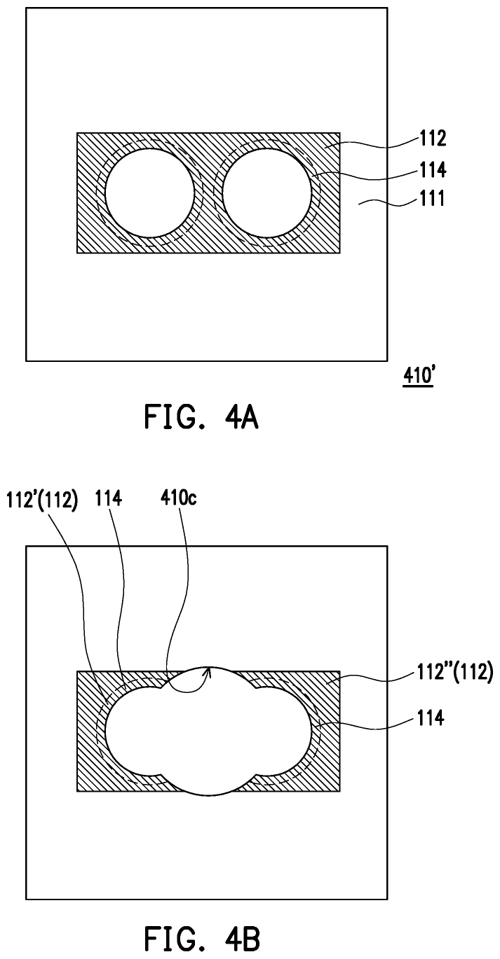

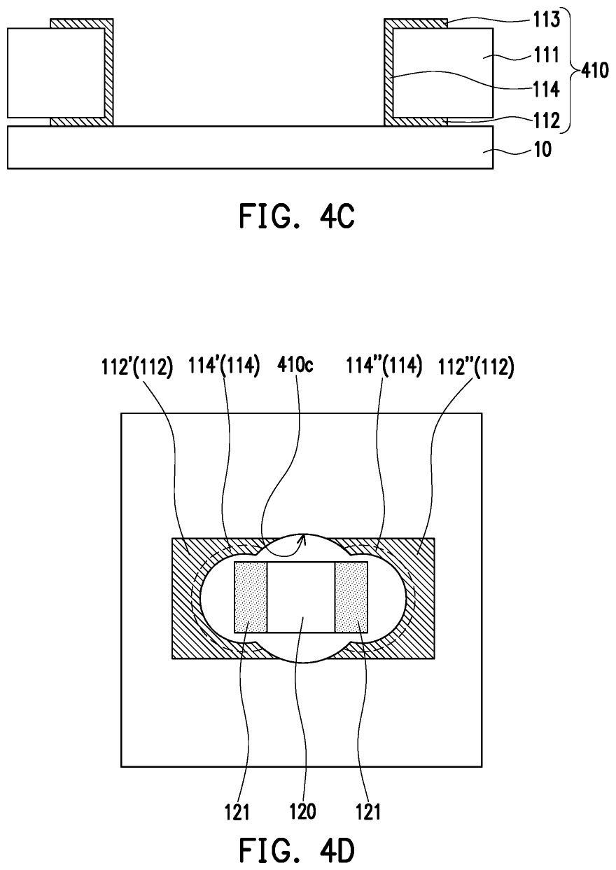

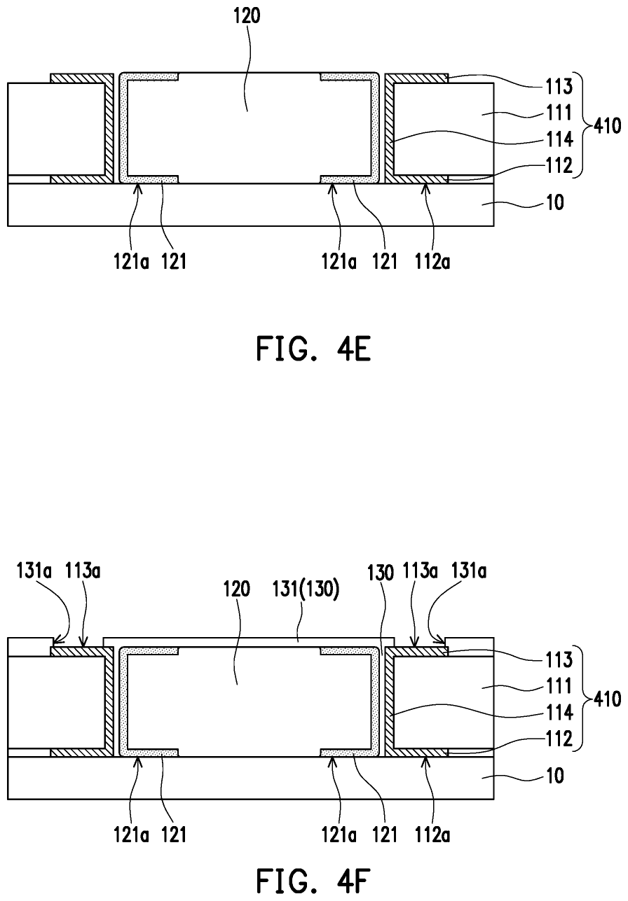

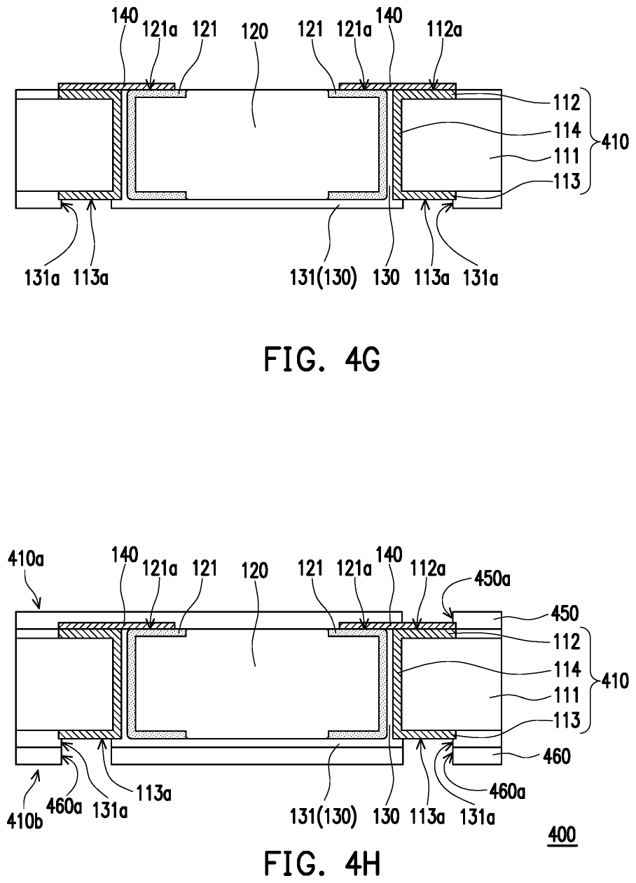

FIG. 4A, FIG. 4B and FIG. 4D are schematic bottom views of a manufacturing method of an embedded component structure according to a fourth embodiment of the invention. FIG. 4C, FIG. 4E to FIG. 4H are schematic cross-sectional views of a manufacturing method of an embedded component structure according to a fourth embodiment of the invention.

The manufacturing processes of the embedded component structure 400 (shown in FIG. 4H) provided in the present embodiment are similar to the manufacturing processes of the embedded component structure 100 provided in the first embodiment, and similar components are marked by identical or similar reference numerals and have similar function, material, or may be formed in a similar manner, and thus relevant descriptions are omitted hereinafter.

Referring to FIG. 4A, a circuit board 410′ is provided. Structurally, the circuit board 410′ in FIG. 4A is similar to the circuit board 110 in FIG. 1A, with the main difference being that the circuit board 410′ has no through hole (not shown because none).

Referring to FIGS. 4B and 4C, a circuit board 410 having a through hole 410c is formed. For example, a portion of the first circuit layer 112 and a portion of the core layer 111 of the circuit board 410′ (shown in FIG. 4A) may be removed by etching, grinding drilling, laser drilling, or other suitable process to form a circuit board 410 having a through hole 410c.

In the embodiment, the through hole 410c may be structurally connected to the at least one conductive through hole 114, but the invention is not limited thereto. In other embodiments, the through hole 410c and the conductive through hole 114 may be separated from each other.

Then, the circuit board 410 having the through hole 410c is disposed on the carrier 10. In some embodiments, for reducing damage or unevenness of the carrier surface 10a (shown in FIG. 1B) of the carrier 10, the circuit board 410 having the through hole 410c may be formed first, and then the circuit board 410 having the through hole 410c may be disposed on the carrier 10.

Referring to FIG. 4D and FIG. 4E, the electronic component 120 is disposed on the carrier 10.

In the embodiment, the circuit board 410 may be disposed on the carrier 10, then, the electronic component 120 is disposed on the carrier 10, and the electronic component 120 is embedded in the through hole 410c of the circuit board 410, but the invention is not limited thereto. In other embodiments, the electronic component 120 may be disposed on the carrier 10, then, the circuit board 410 may be disposed on the carrier 10, and the through hole 410c of the circuit board 410 may be aligned with the electronic component 120 to embed the electronic component 120 into the through hole 410c of the circuit board 410.

In the embodiment, the through hole 410c is disposed between the plurality of conductive through hole 114′ and 114″ and is structurally connectable to the conductive through hole 114′ and 114″, and the electronic component 120 is disposed between the conductive through hole 114′ and 114″. Therefore, the conductive through hole 114′ and 114″ corresponding to the plurality of connection pads 121 of the electronic component 120 are electrically separated from each other by the through hole 410c.

Referring to FIG. 4F, after the circuit board 410 and the electronic component 120 are placed on the carrier 10, and the electronic component 120 is embedded in the through hole 410c, a dielectric material layer 130 is formed on the carrier 10, and the dielectric material layer 130 is at least filled in the through hole 410c (shown in FIG. 4D). The dielectric material layer 130 may include a cover portion 131. The cover portion 131 is disposed outside the through hole 410c and covers the second circuit layer 113. The cover portion 131 has at least one dielectric opening 131a. The dielectric opening 131a may expose the third electrical connection surface 113a of the second circuit layer 113.

Referring to FIG. 4G, the structure of FIG. 4F may be flipped upside down before or after the carrier 10 is removed. After the carrier 10 is removed, the connection circuit layer 140 is formed. The connection circuit layer 140 covers and contacts the first electrical connection surface 112a and each of the second electrical connection surfaces 121a. The connection circuit layer 140 is electrically connected to the second circuit layer 113 through the corresponding conductive through hole 114.

Referring to FIG. 4H, after the connection circuit layer 140 is formed, a first dielectric layer 450 is formed on the first side 410a of the circuit board 410. The first dielectric layer 450 has at least one first dielectric opening 450a. The first dielectric opening 450a exposes a portion of the connection circuit layer 140.

In the embodiment, a second dielectric layer 460 may be formed on the second side 410b of the circuit board 410. The second dielectric layer 460 has at least one second dielectric opening 460a. The second dielectric opening 460a exposes a portion of the second circuit layer 113.

In other embodiments, the first dielectric layer 450 and/or the second dielectric layer 460 may be a dry film solder resist or a liquid photosensitive solder resist.

After the above manufacturing process is performed, an embedded component structure 400 provided in the present embodiment is substantially formed. The embedded component structure 400 of the present embodiment is similar to the embedded component structure 100 of the first embodiment, with the main difference being that the through hole 410c and the at least one conductive through hole 114 of the circuit board 410 may be structurally connected to each other.

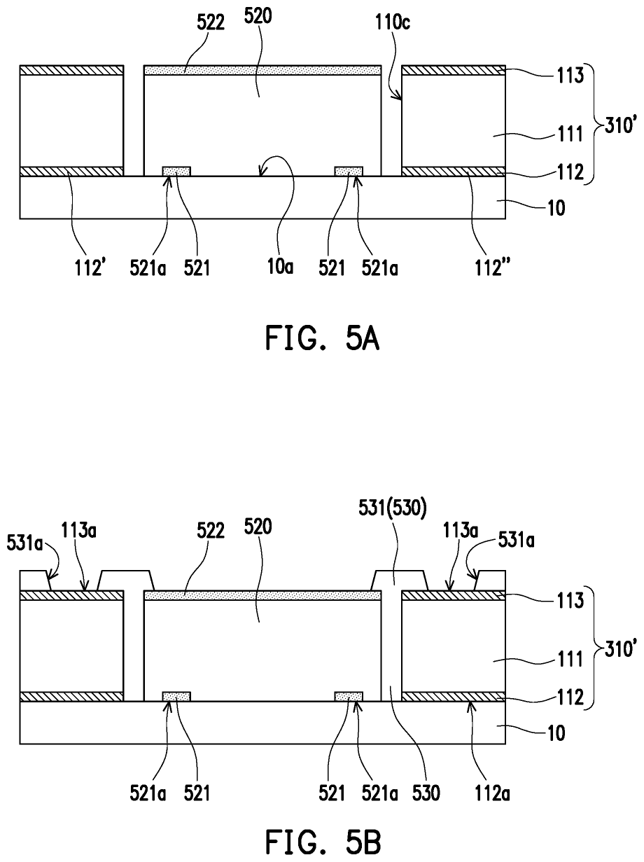

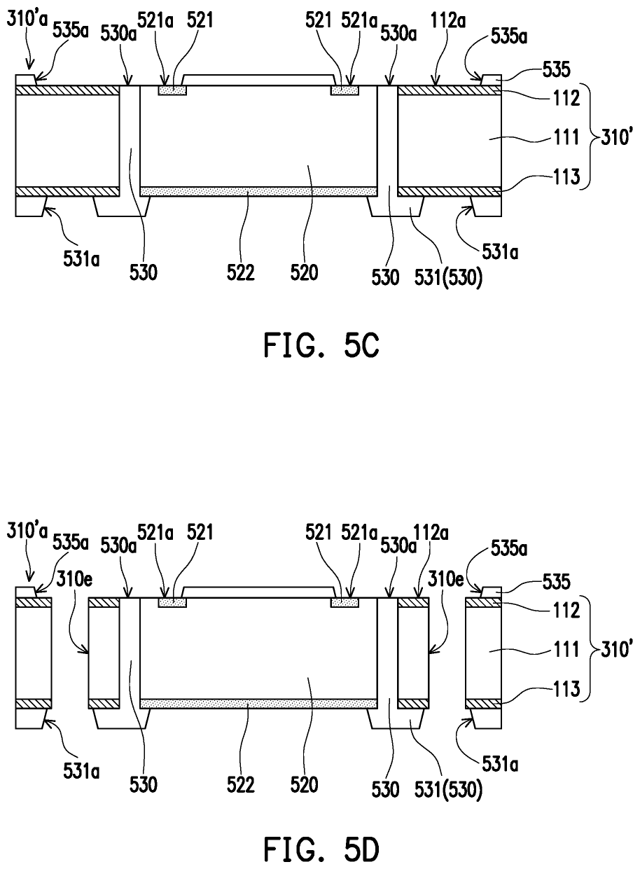

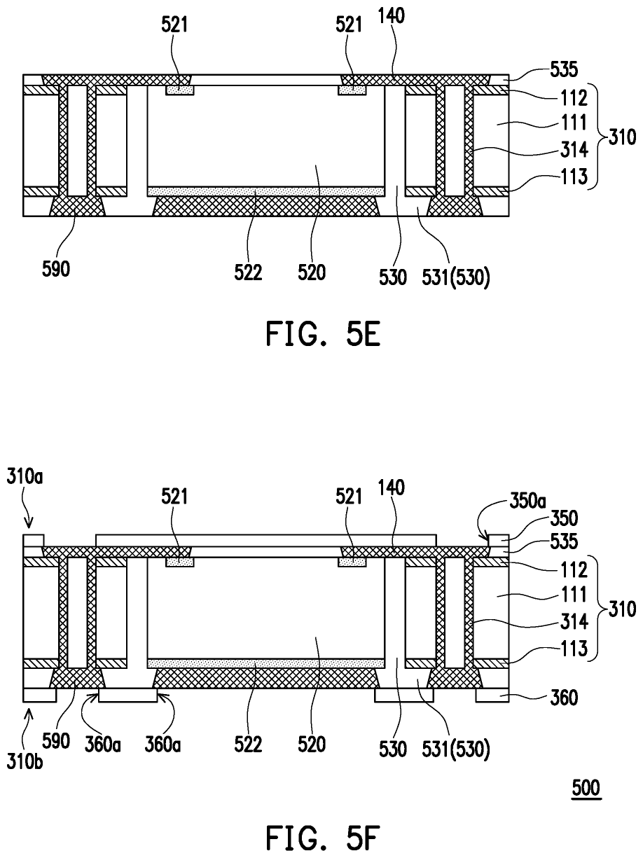

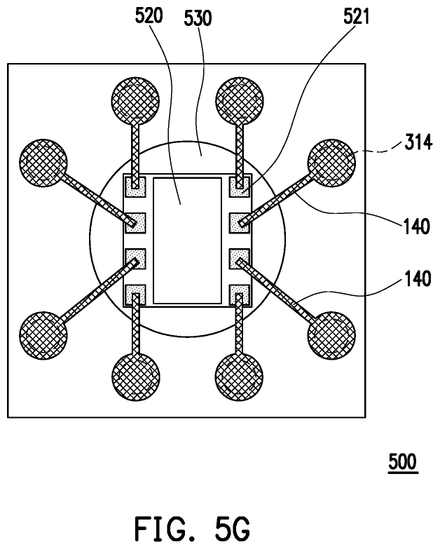

FIG. 5A to FIG. 5F are schematic cross-sectional views of a manufacturing method of an embedded component structure according to a fifth embodiment of the invention. FIG. 5G is a schematic top view of an embedded component according to a fifth embodiment of the invention.

The manufacturing processes of the embedded component structure 500 (shown in FIG. 5F) provided in the present embodiment are similar to the manufacturing processes of the embedded component structure 300 provided in the third embodiment, and similar components are marked by identical or similar reference numerals and have similar function, material, or may be formed in a similar manner, and thus relevant descriptions are omitted hereinafter.

Referring to FIG. 5A, the circuit board 310′ and the electronic component 520 may be disposed on the carrier 10 by steps similar to those of FIGS. 1A to 1C, and the electronic component 520 may be embedded in the through hole 110c.

In the embodiment, the electronic component 520 may have a plurality of first connection pads 521 on one side thereof, the electronic component 520 may have a second connection pad 522 on the other side thereof. The electronic component 520 is disposed on the carrier 10 in such a manner that the second electrical connection surface 521a of each of the first connection pads 521 of the electronic component 520 faces the carrier surface 10a of the carrier 10. In the embodiment, the second electrical connection surface 521a of each of the first connection pads 521 may directly contact the carrier surface 10a of the carrier 10, but the invention is not limited thereto. In other embodiments, if an adhesive layer (not shown) is disposed between the electronic component 520 and the carrier 10, the second electrical connection surface 521a of each of the first connection pads 521 may indirectly contact the carrier 10. For example, a vertical cavity surface emitting laser (VCSEL) die, a light emitting diode (LED) die or other active component is used as the electronic component 520, and the thickness scale thereof is about micrometer to millimeter. In other words, the thickness of the adhesive layer may be very thin compared to the thickness of the electronic component 520. Therefore, in the general visual sense, even if an adhesive layer is disposed between the electronic component 520 and the carrier 10, the electronic component 520 may be regarded as contacting the carrier 10.

In the embodiment, the circuit board 310′ may be disposed on the carrier 10, then, the electronic component 520 is disposed on the carrier 10, and the electronic component 520 is embedded in the through hole 110c of the circuit board 310′, but the invention is not limited thereto. In other embodiments, the electronic component 520 may be disposed on the carrier 10, then, the circuit board 310′ may be disposed on the carrier 10, and the through hole 110c of the circuit board 310′ may be aligned with the electronic component 520 to embed the electronic component 520 into the through hole 110c of the circuit board 310′.

In the embodiment, the thickness of the circuit board 310′ may be the same as or different from the thickness of the electronic component 520, but the invention is not limited thereto. It should be noted that the cross-sectional area of the through hole 110c of the circuit board 310′ should be larger than the cross-sectional area of the electronic component 520 on the side of the first connection pads 521, so that the electronic component 520 is suitably embedded in the through hole 110c of the circuit board 310′, and the first connection pads 521 of the electronic component 520 could be exposed to the outside of the through hole 110c.

Referring to FIG. 5B, after the circuit board 310′ and the electronic component 520 are placed on the carrier 10, and the electronic component 520 is embedded in the through hole 110c (shown in FIG. 5A), a first dielectric material layer 530 is formed on the carrier 10, and the first dielectric material layer 530 is at least filled in the through hole 110c. The first dielectric material layer 530 may include a cover portion 531. The cover portion 531 is disposed outside the through hole 110c and covers the second circuit layer 113. The cover portion 531 has dielectric openings 531a. The dielectric openings 531a may expose the third electrical connection surface 113a of the second circuit layer 113 and the second connection pad 522 of the electronic component 520.

The material and formation manner of the first dielectric material layer 530 may be the same as or similar to the material and formation manner of the dielectric material layer 130 of the foregoing embodiment, and thus is not described in detail herein. That is, the Young's modulus of the core layer 111 is greater than the Young's modulus of the first dielectric material layer 530.

Referring to FIG. 5C, after the first dielectric material layer 530 is formed, the carrier 10 is removed to expose the first electrical connection surface 112a of the first circuit layer 112 and the second electrical connection surface 521a of each of the first connection pads 521. Since the circuit board 310′ and the electronic component 520 are both disposed on the carrier 10 and in contact (direct contact if there is no adhesive layer, or indirectly contact if there is an adhesive layer) with the carrier 10, the first electrical connection surface 112a of the first circuit layer 112 and the second electrical connection surface 521a of each first connection pad 521 may be substantially coplanar.

In the embodiment, if the first dielectric material layer 530 filled in the through hole 110c contacts (including directly contact or indirectly contact as mentioned above) the carrier 10, the dielectric surface 530a of the dielectric material layer 530, the first electrical connection surface 112a of the first circuit layer 112, and the second electrical connection surface 521a of each first connection pads 521 may be substantially coplanar.

In addition, the structure of FIG. 5B may be flipped upside down before or after the carrier 10 is removed, so that after the carrier 10 is removed, a structure as shown in FIG. 5C may be constructed.

Referring to FIG. 5C, after the carrier 10 is removed, a second dielectric material layer 535 is formed on the first side 310′a of the circuit board 310′. The second dielectric material layer 535 has dielectric openings 535a. The dielectric openings 535a may expose the dielectric surface 530a of the first dielectric material layer 530, the first electrical connection surface 112a of the first circuit layer 112, and the second electrical connection surface 521a of each of the first connection pads 521.

The material and formation manner of the second dielectric material layer 535 may be the same as or similar to the material and formation manner of the first dielectric material layer 530, and thus is not described in detail herein.

Referring to FIG. 5D, after forming the second dielectric material layer 535, at least one through hole 310e may be formed on the circuit board 310′ (shown in FIG. 5C) by etching, grinding drilling, laser drilling, or other suitable process. The through hole 310e penetrates the core layer 111, the first circuit layer 112, and the second circuit layer 113.

In the embodiment, since the electronic component 520 has been embedded in the through hole 110c of the circuit board 310′, and the dielectric material layer 530 filled in the through hole 110c may fix the electronic component 520 in the through hole 110c and provide a buffer between the electronic component 520 and the circuit board 310′. Therefore, in the process of forming the through hole 310e, although the electronic component 520 or the circuit board 310′ may be affected by stress (for example, vibration during hole drilling to cause stress between the electronic component 520 or the circuit board 310′), the offset of the electronic component 520 may be reduced.

Referring to FIG. 5E, after the through holes 310e (shown in FIG. 5D) are formed, the connection circuit layer 140 is formed. Further, a conductive material is filled in the through hole 310e to form the conductive through hole 314 by a method similar to the method of forming the connection circuit layer 140. The circuit board 310 having the core layer 111, the first circuit layer 112, the second circuit layer 113, and the conductive through hole 314 may be formed.

In the present embodiment, a circuit layer 590 may be formed on the second circuit layer 113 and/or the second connection pad 522. The way to form the circuit layer 590 may be similar to the aforementioned way to form the connection circuit layer 140, and thus is not described in detail herein. In addition, the dielectric openings 531a of the second dielectric material layer 535 may be further filled with the conductive material used to form the circuit layer 590, so as the circuit layer 590 may be electrically connected to the second circuit layer 113 and/or the conductive through hole 314.

Referring to FIG. 5F and FIG. 5G, after the connection circuit layer 140 and the conductive through hole 314 are formed, the first dielectric layer 350 is formed on the first side 310a of the circuit board 310. The first dielectric layer 350 has at least one first dielectric opening 350a. The first dielectric opening 350a exposes a portion of the connection circuit layer 140 and/or a portion of the conductive through hole 314.

In the embodiment, a second dielectric layer 360 may be formed on the second side 310b of the circuit board 310. The second dielectric layer 360 has at least one second dielectric opening 360a. The second dielectric opening 360a exposes a portion of the second circuit layer 113 and/or a portion of the conductive through hole 314.

Structurally, the embedded component structure 500 of the present embodiment is similar to the embedded component structure 300 of the third embodiment, with the main difference being that the connection pads 521 and 522 of the electronic component 520 have different configurations.

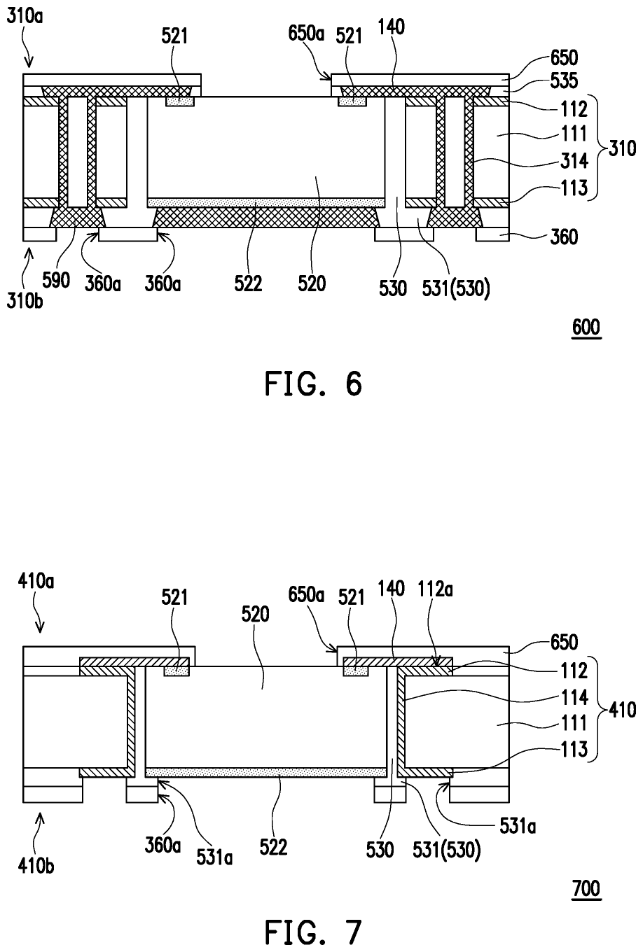

FIG. 6 is a schematic cross-sectional view of an embedded component according to a sixth embodiment of the invention.

The embedded component structure 600 of the present embodiment is similar to the embedded component structure 500 of the fifth embodiment, and similar components are marked by identical or similar reference numerals and have similar function, material, or may be formed in a similar manner, and thus relevant descriptions are omitted hereinafter. Structurally, the embedded component structure 600 of the present embodiment is similar to the embedded component structure 500 of the fifth embodiment, with the main difference being that the first dielectric layer 650 has a first dielectric opening 650a that exposes the electronic component 520.

FIG. 7 is a schematic cross-sectional view of an embedded component according to a seventh embodiment of the invention.

The embedded component structure 700 of the present embodiment is similar to the embedded component structure 600 of the sixth embodiment, and similar components are marked by identical or similar reference numerals and have similar function, material, or may be formed in a similar manner, and thus relevant descriptions are omitted hereinafter. Structurally, the embedded component structure 700 of the present embodiment is similar to the embedded component structure 600 of the sixth embodiment, with the main difference being that the through hole 410c (shown in FIG. 4B) of the circuit board 410 may be structurally connected to the at least one conductive through hole 114 in the embedded component structure 700 of the present embodiment. For example, the circuit board 410 in which the through hole 410c and the conductive through hole 114 are structurally connectable to each other may be formed by the manufacturing method as shown in FIGS. 4A to 4C.

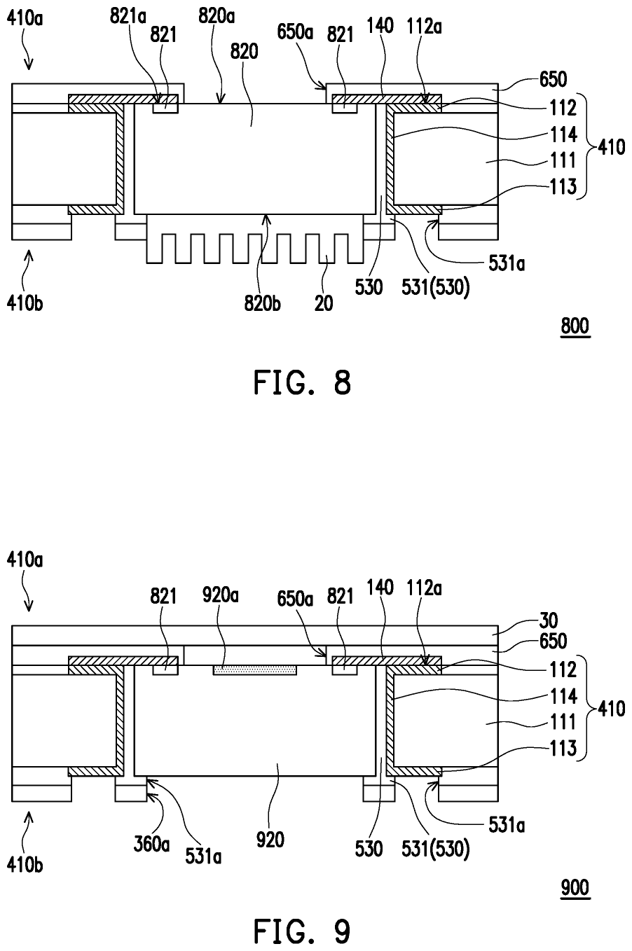

FIG. 8 is a schematic cross-sectional view of an embedded component according to an eighth embodiment of the invention.

The embedded component structure 800 of the present embodiment is similar to the embedded component structure 700 of the seventh embodiment, and similar components are marked by identical or similar reference numerals and have similar function, material, or may be formed in a similar manner, and thus relevant descriptions are omitted hereinafter. Structurally, the embedded component structure 800 of the present embodiment is similar to the embedded component structure 700 of the seventh embodiment, with the main difference being that the electronic component 820 of the embedded component structure 800 is, for example, a chip, a package having a chip, or other electronic component having an active device.

Taking a chip as an example, the connection pad 821 of the electronic component 820 may be a die pad. The connection pads 821 are disposed on the active surface 820a. The first electrical connection surface 112a and the second electrical connection surfaces 821a of the connection pads 821 may be substantially coplanar. The connection circuit layer 140 covers and contacts the first electrical connection surface 112a and each of the second electrical connection surfaces 821a. The connection pad 821 is electrically connected to a corresponding portion of the first circuit layer 112 by the corresponding connection circuit layer 140.

In the embodiment, a heat dissipating component 20 may be disposed on the back surface 820b (e.g., a surface opposite to the active surface 820a) of the electronic component 820. The heat dissipating component 20 may include a heat dissipation plate, a heat dissipation fin, or the like, but the invention is not limited thereto. The heat generated by the electronic component 820 during operation may be transmitted to the outside (or environment) through the heat dissipating component 20, and the embedded component structure 800 may have a better heat dissipation effect, but the invention is not limited thereto.

In the embodiment, the heat dissipating component 20 may be directly contact with the back surface 820b of the electronic component 820, but the invention is not limited thereto. In an unillustrated embodiment, the heat dissipating component 20 and the back surface 820b of the electronic component 820 may have a thermal conductive paste.

In an unillustrated embodiment, a heat dissipating component similar to the heat dissipating component 20 may (also) be disposed on the first dielectric layer 650.

FIG. 9 is a schematic cross-sectional view of an embedded component according to a ninth embodiment of the invention.

The embedded component structure 900 of the present embodiment is similar to the embedded component structure 700 of the seventh embodiment, and similar components are marked by identical or similar reference numerals and have similar function, material, or may be formed in a similar manner, and thus relevant descriptions are omitted hereinafter. Structurally, the embedded component structure 900 of the present embodiment is similar to the embedded component structure 700 of the seventh embodiment, with the main difference being that the electronic component 920 of the embedded component structure 900 is, for example, an optical sensing chip (e.g., a chip including a charge-coupled device (CCD)), an acoustic chip (e.g., a chip including a MEMS device), or a sensing chip suitable for receiving external signals. The electronic component 920 may have a sensing area 920a. The sensing area 920a is adapted to receive an external signal.

In the embodiment, the sensing region 920a may have a cover layer 30 thereon. The cover layer 30 may reduce damage that may be caused to the sensing region 920a. In an embodiment, the cover layer 30 is, for example, a hard coating layer or a coverlay, but the invention is not limited thereto. In an embodiment, the cover layer 30 may be a glass plate, a quartz plate, a rigid plastic plate, or other similar rigid plate.

To sum up, in the embedded component structure of one or more embodiments of the invention, the electronic component and the circuit board are electrically connected via the connection circuit layer therebetween, and the via hole between the electronic component and the circuit board could no need to be formed or omitted. Therefore, the manufacturing process of the embedded component structure could be simpler and has a thinner thickness. In addition, the circuit path between the electronic component and the circuit board may be reduced via the connection circuit layer, and the signal transmission time may be reduced, and the transmission rate between different electronic components may be improved.

It will be apparent to those skilled in the art that various modifications and variations can be made to the structure described in the disclosure without departing from the scope or spirit of the disclosure. In view of the foregoing, it is intended that the disclosure cover modifications and variations provided they fall within the scope of the following claims and their equivalents.

What is claimed is:

1. An embedded component structure, comprising:
a circuit board having a through hole, and the circuit board comprising:
a core layer;
a first circuit layer, disposed on the core layer; and
a second circuit layer, disposed on the core layer opposite to the first circuit layer, wherein the through hole at least penetrates the first circuit layer and the core layer
an electronic component, disposed in the through hole, wherein the electronic component includes a plurality of connection pads exposed to the outside of the through hole;
a dielectric material layer, at least filled in the through hole, wherein the Young's modulus of the core layer is greater than the Young's modulus of the dielectric material layer; and
a connecting circuit layer, covered and contacted a first electrical connecting surface of the first circuit layer and at least one of a second electrical connecting surface of each of the connection pads, wherein the connecting pads are electrically connected to the first circuit layer by the connecting circuit layer.

2. The embedded component structure of claim 1, wherein the dielectric material layer is further filled between each of the connection pads and the first circuit layer and has a dielectric surface coplanar with the first electrical connection surface, and the connecting circuit layer covers and contacts the first electrical connection surface, the dielectric surface, and the second electrical connection surface.

3. The embedded component structure of claim 2, wherein on a cross section perpendicular to the first electrical connection surface, a cross-sectional thickness of the connecting circuit layer on the first electrical connecting surface, a cross-sectional thickness of the connecting circuit layer on the dielectric surface, and a cross-sectional thickness of the connecting circuit layer on the second electrical connecting surface are substantially the same.

4. The embedded component structure of claim 1, wherein a cross-sectional area of the through hole is larger than a surface area of the second electrical connection surface.

5. The embedded component structure of claim 1, further comprising:
a first dielectric layer, disposed on the same side of the first circuit layer as the core layer and covered at least a portion of the first circuit layer and at least a portion of the connection circuit layer, wherein the first dielectric layer includes at least one opening exposing the first circuit layer or the connection circuit layer.

6. The embedded component structure of claim 5, wherein the material of the first dielectric layer includes a solder resist material or a photoimageable dielectric material.

7. The embedded component structure of claim 1, wherein the dielectric material layer includes a cover portion outside the through hole, and the cover portion covers a side of the core layer on which the second circuit layer is disposed and covers at least a portion of the second circuit layer.

8. The embedded component structure of claim 7, wherein the cover portion of the dielectric material layer includes at least one dielectric opening exposing the second circuit layer.

9. The embedded component structure of claim 7, further comprising:
a second dielectric layer, covered the cover portion of the dielectric material layer, wherein the second dielectric layer includes at least one opening exposing the second circuit layer.

10. The embedded component structure of claim 9, wherein the material of the second dielectric layer includes a solder resist material or a photoimageable dielectric material.

11. The embedded component structure of claim 1, wherein the first electrical connection surface of the first circuit layer is coplanar with at least one of the second electrical connection surface of each of the connection pads.

12. The embedded component structure of claim 1, wherein the circuit board further comprising:
at least one conductive through hole, penetrated the core layer to electrically connect the first circuit layer and the second circuit layer.

13. The embedded component structure of claim 12, wherein the through hole is connected to the at least one conductive through hole.

14. A manufacturing method of an embedded component structure, comprising:
providing a carrier;
placing a circuit board on the carrier, wherein the circuit board includes a through hole, and the circuit board comprising:
a core layer;
a first circuit layer, disposed on the core layer; and
a second circuit layer, disposed on the core layer opposite to the first circuit layer, wherein the through hole at least penetrates the first circuit layer and the core layer;
placing an electronic component on the carrier, wherein the electronic component includes a plurality of connection pads, and the connection pads contact the carrier;
forming a dielectric material layer on the carrier after the circuit board and the electronic component are placed on the carrier and the electronic component is embedded in the through hole, the dielectric material layer is at least filled in the through hole, and the Young's modulus of the core layer is greater than the Young's modulus of the dielectric material layer;
removing the carrier to expose the first circuit layer and the connection pads, wherein a first electrical connection surface of the first circuit layer is coplanar with a second electrical connection surface of each of the connection pads; and
forming a connection circuit layer after the carrier is removed, wherein the connection circuit layer covers and contacts the first electrical connection surface and the at least one of the second electrical connection surfaces.

15. The manufacturing method of the embedded component structure of claim 14, wherein the circuit board further comprising:
at least one conductive through hole, penetrated the core layer to electrically connect the first circuit layer and the second circuit layer.

16. The manufacturing method of the embedded component structure of claim 15, wherein the through hole is connected to the at least one conductive through hole.

17. The manufacturing method of the embedded component structure of claim 14, further comprising:
forming a first dielectric layer after the connection circuit layer is formed, wherein the first dielectric layer covers at least a portion of the first circuit layer and at least a portion of the connection circuit layer.

18. The manufacturing method of the embedded component structure of claim 17, wherein the material of the first dielectric layer includes a solder resist material or a photoimageable dielectric material.

19. The manufacturing method of the embedded component structure of claim 14, further comprising:
forming at least one through hole on the circuit board and penetrated the core layer, the first circuit layer, and the second circuit layer after the dielectric material layer is formed; and
filling a conductive material into the at least one through hole to form at least one conductive through hole penetrated the core layer, wherein the at least one conductive through hole is electrically connected the first circuit layer and the second circuit layer.

20. The manufacturing method of the embedded component structure of claim 14, wherein the dielectric material layer includes a cover portion outside the through hole, and the cover portion covers a side of the core layer on which the second circuit layer is disposed and covers at least a portion of the second circuit layer.

21. The manufacturing method of the embedded component structure of claim 20, further comprising:
forming at least one dielectric opening on the cover portion of the dielectric material layer, wherein the at least one dielectric opening exposes the second circuit layer.

22. The manufacturing method of the embedded component structure of claim 20, further comprising:
forming a second dielectric layer to cover the cover portion of the dielectric material layer.

23. The manufacturing method of the embedded component structure of claim 22, further comprising:
forming at least one second opening on the second dielectric layer, wherein the at least one second opening exposes the second circuit layer.

24. The manufacturing method of the embedded component structure of claim 22, wherein the material of the second dielectric layer includes a solder resist material or a photoimageable dielectric material.
